(19) United States
(12) Patent Application Publication
(10) Pub. No.: US 2008/0012109 A1
(43) Pub. Date: Jan. 17, 2008

(54) Method for the packaging of optical or optoelectronic components, and optical or optoelectronic package element producible according to the method

(75) Inventors: Joern Besinger, Landshut (DE); Sabine Pichler-Wilhem, Landshut (DE); Dieter Goedeke, Landshut (DE); Luise Sedlmeier, Oberwattenbach (DE)

Correspondence Address: DEMONT & BREYER, LLC, 100 COMMONS WAY, Ste. 250, HOLMDEL, NJ, 07733, US

(73) Assignee: SCHOTT AG, Mainz (DE)

(21) Appl. No.: 11/772,640

(22) Filed: Jul. 2, 2007

(30) Foreign Application Priority Data
Jul. 5, 2006 (DE) 10 2006 031 358.5

(51) Int. Cl. H01L 23/02; C03C 27/02; G02B 1/06

(52) U.S. Cl. 257/680; 359/665; 65/59.1; 257/E23.18

(57) ABSTRACT

The invention relates to a method for producing package parts for optical or optoelectronic components. To this end a metal package element is bonded to a transparent package element by means of a glass solder ring, the glass solder being brought in contact with the metal package element and the transparent package element, and the metal package element being inductively heated by an alternating electromagnetic field generated by an induction coil, so that the glass solder is heated and fused in contact with the metal package element and a hermetic, preferably ring-shaped bond between the metal package element and the transparent package element being produced by fusing and subsequently solidifying the glass solder.

Optoelectronic components are often encapsulated with metal packages according to the prior art. These packages often comprise a metal package element as well as a transparent package element for the input or output of light. In order to produce a hermetic bond between the transparent package element and the metal package element, glass solder is furthermore often used. The glass solder is either applied in the form of a paste or employed as a sintered shaped part in the capacity of a solder ring. The fusion per se is generally carried out in a tube oven or batch oven. The oven process itself can be controlled only with difficulty since, especially for mass production, elaborate magazines are used which provide only a difficult to control heat distribution on the components themselves. This makes the reproducibility of the fusion more difficult.

Furthermore, the heating and cooling gradients are very flat and the process duration is correspondingly long. In particular the long holding time required in the region of the processing temperatures of the glass solder, which is necessary in order to ensure that all the package parts are reliably bonded to one another, has the effect that the glass can rise uncontrollably along the package wall so that the glass component important for the application becomes wetted in the optically relevant region. Another disadvantage of the previously known methods is that, in the case of composite glass solders, demixing of the basic glass and the fillers often takes place here. This demixing has an unfavorable effect on the thermal expansion coefficient and therefore the quality of the fusion. In particular, such demixing may also lead to a non-hermetic bond and therefore to the ingress of moisture or air/gas into the finished component. Another disadvantage of the previously known methods is that glass solders with an elevated crystallization susceptibility are very difficult to process. Particularly when the crystallization temperature lies in the region of the soldering temperature, the long process times lead to increased precipitation of crystals. The solder is then no longer sufficiently capable of wetting the bonding partners and providing an intimate bond. The change in the thermal expansion coefficient furthermore leads to a mismatch and therefore stresses in the component, which can lead to the effects already described above. The addition of fillers can furthermore impair the controllability of the fusion. Conventionally used glass solders usually contain high proportions of cations susceptible to reduction, such as lead (II/IV) or bismuth (III) in ionic form. In order to prevent metallic precipitations of these elements, fusion must be carried out in an oxidizing atmosphere. This in turn leads to oxidation of the metal part, which necessitates a further process step for reduction of the metal below the transition temperature of the solder glass, for example with the addition of hydrogen gas.

The metal parts used are often selected from the class of NiFeCo or NiFe alloys or cutting steels. In order to improve the weldability and for corrosion protection, these must be provided with electrolytic layers such as for example gold, Ni, Ag etc. the thermal stability of these layers is limited, however, which prohibits the use of higher-melting glass solders.

Control of the temperature induced on the component is furthermore generally possible only empirically. The reason for this is the strong effect due to the mass and material of the magazines used. Above all in the case of solders susceptible to crystallization, changes may therefore take place in the specific material properties, which even lead ultimately to rejects.

Yet another disadvantage of the previously known production technique is the lack of flexibility for product changes and pattern loading, since these entail increased outlay.

Fusing optically coated windows, lenses and similar components is particularly temperature-critical when they consist of metal oxides or comprise metal oxide coatings which, in the range of the processing temperatures, enter into phase transitions that in turn modify the optical properties.

It is therefore an object of the invention to avoid the aforementioned disadvantages in the bonding of package elements for optical or optoelectronic components by means of glass solder. This object is directly achieved in an extremely surprisingly simple way by the subject-matter of the independent claims. Advantageous configurations and refinements of the invention are specified in the respective dependent claims.

Accordingly, the invention provides a method for the packaging of optical or optoelectronic components, in which a metal package element is bonded to a transparent package element by means of a glass solder ring, the glass solder being brought in contact with the metal package element and the transparent package element, and the metal package element being inductively heated by an alternating electromagnetic field generated by an induction coil, so that the glass solder is heated and fused in contact with the metal package element and a hermetic, preferably ring-shaped bond between the metal package element and the transparent package element being produced by the fusion and subsequent solidification. The term “transparent” in the context of the invention does not refer only to package elements which are transparent in the visible spectral range. Rather, a package element which is transmissive for at least one spectral range of light is to be understood as a transparent package element. Accordingly, besides transparency in the visible spectral range, the package component may alternatively or additionally also be transparent in the infrared and/or ultraviolet spectral range.

Furthermore, a ring-shaped bond is not only intended to mean for instance an annular bond. Rather, a ring-shaped bond is generally intended to mean a continuous circumferential structure enclosing an inner region. For example, such a ring-shaped bond may also have a rectangular, square or generally polygonal shape.

An optocap is thereby obtained for the hermetic packaging of an optical or optoelectronic component, comprising a metal package element and a transparent package element for the output and/or input of light from and/or into the package, the metal package element and the transparent package element being bonded by means of a preferably ring-shaped glass solder bond, the glass solder bonding being carried out by heating essentially only via the inductively heated metal package element.

By the heating according to the invention, the energy input for heating can be controlled directly. In this way, very good reproducibility is achieved when bonding the package elements by the glass solder.

According to one embodiment of the invention, a shaped glass solder part is arranged and fused between the metal package element and the transparent package element. By the use of prefabricated shaped glass solder parts, a very high throughput may be achieved since pretreatment steps can be obviated.

According to a further alternative or additional embodiment of the invention, however, a solder bead may be applied as a paste onto at least one of the package elements. This may, for example, be done with a suitable dispenser. The paste is subsequently dried and organic constituents are optionally burnt out before the package elements are joined together. This embodiment of the invention is advantageous so that good contact of the glass solder with the package elements can already be provided when heating. This applies particularly when the glass solder is applied onto the metal package element. In this case, there is already very good thermal contact with the metal package element when heating, so that the fusion process is accelerated.

Overall, substantially shorter process times can be achieved with the invention by direct heating of the metal package element compared with a conventional oven heating process, since the heating in an oven takes place only directly via the heated air and only comparatively little energy transfer therefore takes place. Conversely, with the induction heating according to the invention, the metal package element can already be soldered to the transparent package element within a total soldering time of only at most 2 minutes, preferably at most 90 seconds, particularly preferably at most 60 seconds or even less than 30 seconds by the action of the induction field.

Owing to the accelerated soldering, detrimental diffusion processes and reactions are impeded in the glass or between the constituents of the optocap. Particular examples of these include crystallization, reduction of the glass solder and/or oxidation of the metal package element, particularly when using process gases (forming gas, argon, etc.) or in a vacuum. In contrast to processes by means of LASER or IR sources, the soldering according to the invention is also not dependent on the absorptivity of the solder in respect of the incident wavelength.

In this way, for example, undesired demixing in the glass solder can also be prevented. The invention also permits the use of lead-free glass solders, for example, which otherwise are rather unsuitable for the application field of packaging optoelectronic components owing to their generally higher processing temperature and/or transition temperature compared with glass solders containing lead. It is precisely composite solders containing lead, however, that are often susceptible to demixing which may lead to the formation of non-hermetically sealed glass solder bonds.

Owing to the direct heating of the metal package element according to the invention and the steep heating gradients thus achievable, a glass solder with a transition temperature of at least 400° C., preferably at least 450° C. may be used according to another refinement of the invention.

The inductor heating of the metal package element also makes it possible to use otherwise difficult material combinations. For example, it has been found that with the invention a metal package element comprising highly expansive metal with a thermal expansion coefficient in the range of from 13·10⁻⁶ K⁻¹ to 20·10⁻⁶ K⁻¹, such as highly expansive stainless steel, even austenitic stainless steel in a preferred embodiment, can also readily be bonded to a transparent package element by means of the glass solder bond. In particular, package elements made of austenitic stainless steel may also be bonded to solder glass package elements.

Glass package elements are preferably used as transparent package elements. The invention is nevertheless also applicable for other materials, for example crystalline transparent package elements. Furthermore, transparent package element may also have an optical coating. Such a coating may be a filter coating, for example, in which case it may in particular also comprise an interference coating having one or more layers. Such an interference coating may fulfill a wide variety of functions. For example, the interference coating may comprise antireflection or blooming, or also act as a beam splitter or dichroic mirror, broadband or bandpass filter. Such optical components often comprise one or more metal oxide layers, which are thermally sensitive in respect of their morphology. In some metal oxide layers, for instance, phase transitions may take place at sufficiently high temperatures.

This may entail changes in the layer thickness or the transmission. Yet since the heating times are significantly reduced by means of the invention, it is even possible to bond transparent package elements which have an optical coating comprising a material that experiences a phase transition at a temperature below 600° C.

Since essentially only the metal package element is heated by the inductive heating according to the invention, according to one refinement of the invention the transparent package element may be kept below the processing temperature of the glass solder, and in particular below its own transition temperature, in a region below the glass solder ring during the fusion. Such phase transitions, which otherwise would detrimentally effect the optical properties of the coating of the transparent package element, can therefore also be suppressed.

In the simplest case, a glass window in the form of a glass wafer is used as the transparent package element. Besides glass windows, it is also possible to use glass-ceramic windows, sapphire windows, quartz windows or silicon windows as transparent package elements. A silicon window is in this case an example of a package element which is transparent only for infrared light.

According to another refinement of the invention, a lens as a transparent package element is bonded to the metal package element. Regardless of the configuration of the transparent package element, the transparent package element may be put into the cap-shaped metal package element so that the transparent package element is arranged internally in the sleeve of the metal package element after bonding by the glass solder.

It is likewise possible, and advantageous depending on the application, to arrange and solder the transparent package element externally on the metal package element.

Furthermore, a plurality of metal package elements may also be arranged beside and/or above one another and simultaneously bonded to transparent package elements by fusing the glass solder. To this end, a single correspondingly dimensioned induction coil or an arrangement of a plurality of induction coils may be used.

An optocap produced according to the invention by bonding the transparent package element to the metal package element may, for example, be used for encapsulating a laser or a photodiode, particularly for data transmission or for optical disk drives. Optical liquid lenses may furthermore be encapsulated with optocaps producible according to the invention. Such liquid lenses may for example be used for cameras in mobile telephones, digital telegrams, in medical technology, media technology, or for applications in the automotive field.

The invention will be explained in more detail below with the aid of exemplary embodiments and with reference to the appended drawings. Reference numerals which are the same denote identical or similar parts.

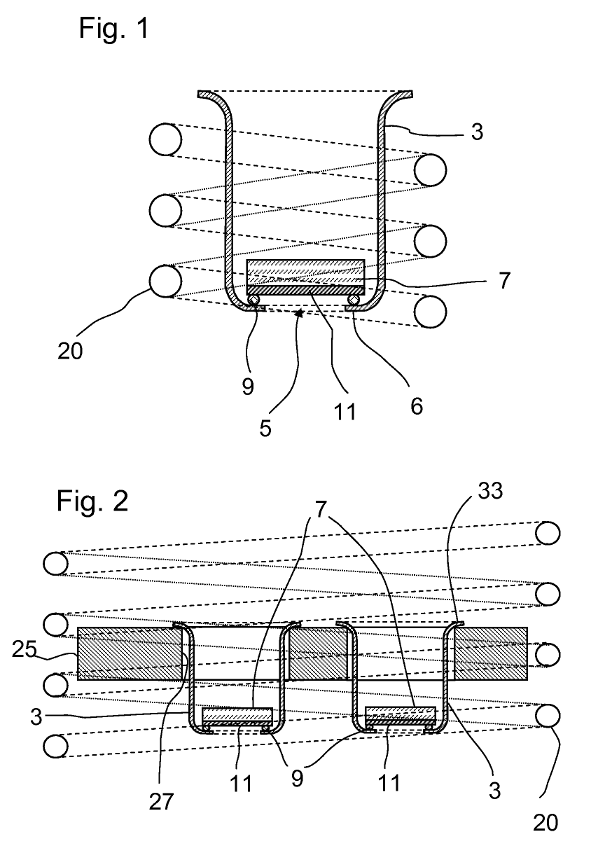

FIG. 1 shows an arrangement for carrying out the method according to the invention with parts of an optocap,

FIG. 2 shows an optocap with bonded package elements,

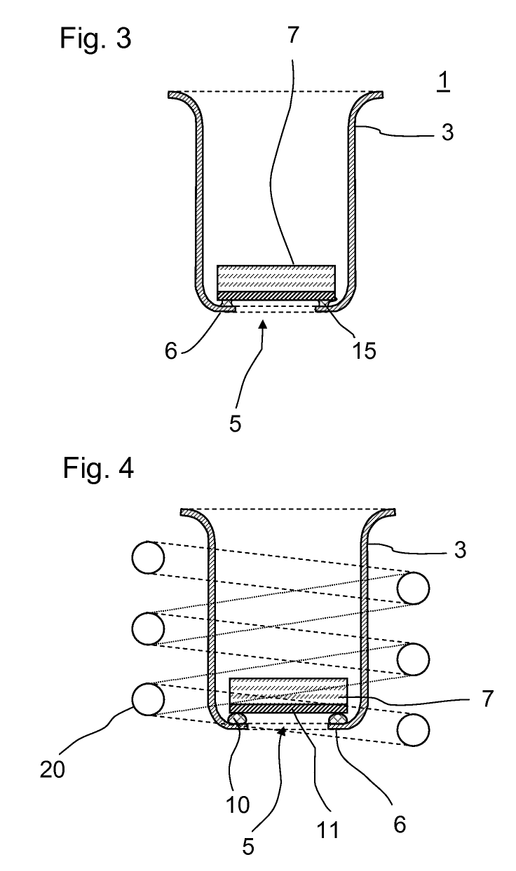

FIG. 3 shows a variant of the embodiment shown in FIG. 1,

FIG. 4 shows a variant of the embodiment shown in FIG. 1, and

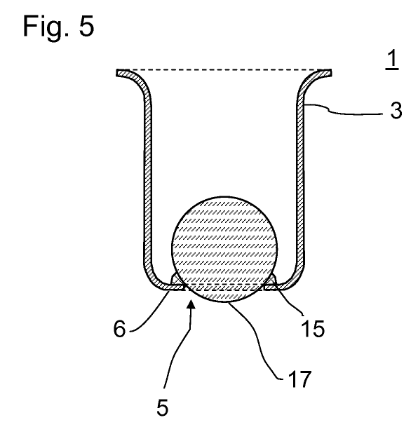

FIG. 5 shows a variant of the optocap shown in FIG. 2, with a lens as the transparent package element.

FIG. 1 shows a schematic view of an arrangement for bonding package elements of an optocap by means of glass solder, as well as the parts of the optocap which are to be bonded. The optocap comprises a metal package element 3 in the form of the sleeve with an opening 5, which is delimited by an inwardly projecting edge 6. A window 7 in the form of a glass wafer, which is put into the sleeve so that it is arranged internally, is provided as the transparent package element in the exemplary embodiment shown in FIG. 1.

A shaped glass solder part 9, which rests on the inwardly projecting edge 6 of the metal package element 3, is furthermore put into the sleeve of the metal package element 3 before fitting the transparent window 7. Accordingly, after fitting the window 7, the shaped glass solder part 9 is arranged between the metal package element 3 and the window 7. In order to prevent the glass window from falling out before or during fusion of the glass solder, the metal package element 3 is preferably held or mounted with the opening 5 pointing downward.

In the exemplary embodiment according to FIG. 1, the window 7 furthermore has an optical interference coating 11. This interference coating 11 may even contain a material, for instance a metal oxide, which experiences a phase transition at a temperature below 600° C. One example of such a material is titanium oxide which, depending on the morphology, may change from an amorphous to a crystalline phase or from one crystalline phase to another crystalline phase. Owing to its high-index optical properties, titanium oxide per se is particularly suitable for interference layers or interference layer systems. Here, however, such a change in the morphology of a titanium oxide layer may take place in a conventional oven process if low-melting glass solders are not used.

Conversely, as shown in FIG. 1, the heating is carried out inductively by means of an induction coil 20 which is fed with a radiofrequency current, that generates eddy currents in the electrically conductive material of the metal package element 3 which directly heat the metal package element 3. The dielectric transparent package element 7 is not, or at least not substantially heated by the alternating field of the induction coil, however. Heating of the transparent package element with the interference coating 11 accordingly now takes place only indirectly via the glass solder. The window 7 and in particular the interference coating 11 deposited on the window, therefore remains below the temperature which is needed for fusing the glass solder of the shaped glass solder part 9 in the optically relative region inside the opening 5 of the metal package element 3. In particular, the transparent package element or a coating applied thereon also remains below its own transition temperature.

On the other hand, the shaped glass solder part 9 is heated up to or above the processing temperature of the glass solder through contact with the metal package element 3, so that the glass solder fuses and provides a ring-shaped hermetic glass solder bond extending along the edge 6 around the opening 5. Since the heating of the glass solder via the metal package element 3 takes place very quickly, the glass solder is prevented from rising uncontrollably along the package wall and being able to wet the window important for the application in the optically relevant region.

In order to fuse the glass solder, it is heated via the inductively heated metal package element 3 to a soldering temperature above the softening temperature E_{w}, preferably up to or above the processing temperature. The glass solders usable for induction heating may have transition temperatures above 400° C., and even readily above 450° C.

Soldering temperature in the context of the invention is intended to mean the temperature of the glass solder at which the viscosity lies in the range of from 10^{7.6} to 10² dPa·s, preferably in the range of from 10⁶ to 10⁴ dpa*s. Owing to their short heating time possible by virtue of the induction heating, it is even possible to use lead-free glass solder which generally has a higher processing temperature compared with glass solder containing lead.

The fusion or softening of the glass solder by means of inductive heating, via the metal package element 3, moreover very generally has advantages over conventional heating in an oven. For example in the case of composite glass solders, demixing of the glass solder can be counteracted and also uncontrolled wetting of the walls of the metal package element 3 and in particular of the transparent package element can be counteracted owing to the steeper heating gradient, and concomitantly a shorter process time, achievable by the inductive heating. Composite glass solders are glass solders whose inert i.e. unreactive fillers are added in order to influence the thermal expansion coefficient. Suitable fillers are for example zirconia, cordierite or â-eukryptite, which reduce the thermal expansion of the overall structure.

If the time taken for heating the glass solder is too long then demixing of these fillers may take place, which then consequently leads to an inhomogeneous thermal expansion of the glass solder material. During the subsequent solidification of the glass solder, thermally induced stresses may then occur which lead to cracks, so that the glass solder bond is no longer hermetically sealed.

The induction coil 20 is for inductive heating with radiofrequency alternating current. Preferred frequencies for the alternating current generally lie in the range of from 50 kHz to 750 kHz. In order to avoid excessive heating of the coil per se, the coil may also be cooled with liquid, in particular cooled with water. To this end a tubular conductor, through which the coolant flows, is used for the coil.

Unlike as shown in the schematic representation of FIG. 1, a plurality of package elements 3 may also be arranged beside and/or above one another and processed simultaneously with transparent package elements 7 in the induction field by fusing the glass solder. Such an exemplary embodiment is represented in FIG. 2. Similarly as the arrangement represented in FIG. 1, here again the metal package elements 3 are arranged with their opening 5 pointing downward. A dielectric support plate 25 with holes 27 is provided for holding the metal package elements 3. The dielectric support plate 25 is arranged so that the holes 27 are positioned in front of the coil 20, or inside it as shown by way of example in FIG. 2. The metal package elements 3, with shaped glass solder parts 9 and transparent package elements 7 arranged therein, are put into the holes 27 of the dielectric support plate 25 and then processed in parallel by fusing or softening the glass solder by means of the induction field of the coil 20.

FIG. 3 shows an optocap 1 such as may be produced by bonding the metal package element 3 to the transparent package element 7 by means of an arrangement as schematically shown in FIG. 1 or FIG. 2. Fusing the glass solder has generated a ring-shaped hermetic glass solder bond, extending along the edge 6 around the opening 5 of the metal package element 3, between the two package elements 3 and 7.

FIG. 4 shows a variant of the arrangement shown in FIG. 1. In contrast to the arrangement shown in FIG. 1, instead of a shaped solder glass part 9, the glass is applied as a paste in the form of a ring-shaped glass solder bead 10 onto the edge 6 around the opening 5. After the paste has dried, the two package elements 3 and 7 can then be hermetically bonded to one another by fusing the glass solder, correspondingly as described with the aid of FIG. 1 or FIG. 2. The heating process is adjusted in this case so that organic constituents of the glass solder bead 10 are burnt out before the glass solder is fused. The glass solder bead 10 is preferably applied with a dispenser, internally onto the edge 6 of the package element 3 through the opening of a dispenser needle.

FIG. 5 shows a variant of the optocap 1 shown in FIG. 3. In the exemplary embodiment of an optocap 1 as shown in FIG. 5, instead of a window 7, an optical element is used as the transparent package element. In particular, a spherical lens 17 as the transparent package element is bonded to the transparent package element 3 by means of a ring-shaped hermetic glass solder bond 15 in the exemplary embodiment shown.

Unlike as represented in FIGS. 1 to 5, it is likewise also possible for the transparent package element 7 to be arranged and soldered externally on the metal package element 3. In the example shown in FIG. 5, this has the advantage that an increased internal space of the optocap 1 is achieved for a given size of the metal package element 3.

It is clear to the person skilled in the art that the invention is not restricted to the exemplary embodiments described above. Rather, the individual features of the exemplary embodiments may also be combined with one another in a wide variety of ways.

1. A method for the packaging of optical or optoelectronic components, in which a metal package element is bonded to a transparent package element by means of glass solder, the method comprising:
bringing the glass solder in contact with the metal package element and the transparent package element; and
inductively heating the metal package element is by an alternating electromagnetic field generated by an induction coil, so that the glass solder is heated and fused in contact with the metal package element and a hermetic bond between the metal package element and the transparent package element is produced by fusing and subsequently solidifying the glass solder.

2. The method as claimed in claim 1, wherein a shaped glass solder part is arranged and fused between the metal package element and the transparent package element.

3. The method as claimed in claim 1, wherein a solder bead is applied as a paste onto at least one of the package elements.

4. The method as claimed in claim 1, wherein the transparent package element and the metal package element are bonded to one another within a total soldering time of only at most 2 minutes by the action of the induction field.

5. The method as claimed in claim 1, wherein a lead-free glass solder is used.

6. The method as claimed in claim 1, wherein a glass solder with a transition temperature of at least 400° C. is used.

7. The method as claimed in claim 1, wherein a metal package element comprising austenitic stainless steel is bonded to a transparent package element by means of the glass solder bond.

8. The method as claimed in claim 1, wherein a glass package element is bonded to the metal package element by means of the glass solder bond.

9. The method as claimed in claim 1, wherein a transparent package element provided with an optical coating is bonded to the metal package element by means of the glass solder bond.

10. The method as claimed in claim 1, wherein a transparent package element provided with an interference coating is bonded to the metal package element.

11. The method as claimed in claim 1, wherein a transparent package element provided with an optical coating is bonded by the glass solder, wherein the material for the optical coating experiences a phase transition at a temperature below 600° C.

12. The method as claimed in claim 1, wherein an optical component as part of the transparent package element is bonded to the metal package element.

13. The method as claimed in claim 1, wherein a lens or a beam splitter is bonded to the metal package element.

14. The method as claimed in claim 1, wherein the transparent package element remains below its own transition temperature in a region below the glass solder during the fusion.

15. The method as claimed in claim 1, wherein the transparent package element is put into a cap-shaped metal package element, so that the transparent package element is arranged internally in the sleeve of the metal package element after bonding by the glass solder.

16. The method as claimed in claim 1, wherein the transparent package element is arranged and soldered externally on the metal package element.

17. The method as claimed in claim 1, wherein a plurality of metal package elements are arranged beside and/or above one another and simultaneously bonded to transparent package elements by fusing the glass solder.

18. A method for bonding package elements for the packaging of optical or optoelectronic components by means of glass solder, the method comprising inductively heating one or more of the package elements by means of eddy currents generated by an electromagnetic field in an electrically conductive material.

19. An optocap for the hermetic packaging of an optical or optoelectronic component, comprising a metal package element and a transparent package element for the output and/or input of light from and/or into the package, wherein the metal package element and the transparent package element are bonded by means of a glass solder bond produced in accordance with the method of claim 1.

20. The optocap as claimed in claim 19, wherein the transparent package element comprises a glass window, glass-ceramic window, sapphire window, quartz window or a silicon window.

21. The optocap as claimed in claim 19, wherein the transparent package element has a filter coating.

22. The optocap as claimed in claim 19, wherein the transparent package element comprises a lens.

23. The optocap as claimed in claim 19, for the encapsulation of
a laser,
a photodiode,
an optical sensor, or
a liquid lens for digital cameras.

24. An optical liquid lens encapsulated by an optocap according to claim 19.
